(19) United States
(12) Patent Application Publication
(10) Pub. No.: US 2026/0113980 A1
(43) Pub. Date: Apr. 23, 2026

(54) BACKSIDE VIA TO POWER RAIL VIA CONNECTION

(71) Applicant: International Business Machines Corporation, Armonk, NY (US)

(72) Inventors: Xiaoli He, Clifton Park, NY (US); Ruilong Xie, Niskayuna, NY (US); Tao Li, Slingerlands, NY (US); HUIMEI ZHOU, Albany, NY (US); Xiaoming Yang, Clifton Park, NY (US); Nicolas Jean Loubet, GUILDERLAND, NY (US)

(21) Appl. No.: 18/921,149

(22) Filed: Oct. 21, 2024

(51) Int. Cl. H01L 29/417; H01L 21/768; H01L 21/8234; H01L 23/522; H01L 27/088; H01L 29/06; H01L 29/423; H01L 29/66; H01L 29/775; H01L 29/786

(52) U.S. Cl. CPC H10D 30/6729; H10D 84/0149; H10D 84/038; H10D 84/83; H10W 20/023; H10W 20/056; H10W 20/076; H10W 20/42; H10D 30/014; H10D 30/43; H10D 30/6735; H10D 30/6757; H10D 62/121

(57) ABSTRACT

Embodiments of present invention provide a semiconductor structure. The semiconductor structure includes a first and a second transistor; a power rail via between the first and the second transistor; a backside via below the power rail via, the backside via having a first portion directly contacting the power rail via and a second portion underneath the first portion; and an isolation spacer surrounding the second portion of the backside via. The backside via further includes a third portion underneath the second portion. A backside capping layer underneath the isolation spacer surrounds the third portion of the backside via. A method of forming the same is also provided.

### BACKGROUND

The present application relates to manufacturing of semiconductor integrated circuits. More particularly, it relates to forming a backside via to power rail via connection and the structure formed thereby.

As semiconductor industry moves towards smaller node, backside power distribution network (BSPDN) is introduced as a mean to further increase density of devices in a chip by moving some functions such as power distribution to the backside of the chip while leaving mostly signal routing functions at the frontside of the chip.

Generally, BSPDN is designed to provide power to backside power rail (BSPR) at the backside of the chip, and in-turn the BSPR provides the power from the BSPDN to active front-end-of-line (FEOL) devices such as, for example, field-effect-transistors (FETs) through power rail via. The power rail via is usually placed between active devices, often in the cell boundary area, where the tight spacing between active devices makes it difficult to form backside via contacting the power rail via without causing short to, for example, source/drain regions of the active devices nearby.

### SUMMARY

Embodiments of present invention provide a semiconductor structure. The semiconductor structure includes a first and a second transistor; a power rail via between the first and the second transistor; a backside via below the power rail via, the backside via having a first portion directly contacting the power rail via and a second portion underneath the first portion; and an isolation spacer surrounding the second portion of the backside via. The isolation spacer ensures that the backside via is insulated from a semiconductor layer of a semiconductor substrate upon which the first and the second transistor are formed.

According to one embodiment, the semiconductor structure further includes a shallow trench isolation (STI) layer, the STI layer surrounding the first portion of the backside via. The STI layer insulates the backside via from the semiconductor layer as well.

In one embodiment, the STI layer surrounds a lower portion of the power rail via and is directly on top of the isolation spacer.

According to another embodiment, the semiconductor structure further includes a backside capping layer, where the backside via has a third portion underneath the second portion and the backside capping layer surrounds the third portion of the backside via.

In another embodiment, sidewalls of the first portion, the second portion, and the third portion of the backside via are vertically aligned with one another and substantially vertically aligned with sidewalls of the power rail via.

In yet another embodiment, a top surface of the backside capping layer is coplanar with a bottom surface of the isolation spacer.

In one embodiment, the power rail via includes a conductive core and a core liner and the core liner covers the conductive core at sidewalls of the power rail via.

In another embodiment, the power rail via is insulated from source/drain regions of the first and the second transistor by the core liner.

In yet another embodiment, conductive core of the power rail via is in direct contact with the backside via and a width of the conductive core at a bottom thereof is less than a width of the backside via.

Embodiments of present invention provide a method of forming a semiconductor structure. The method includes creating a first via opening between a first and a second transistor from a frontside of a substrate; forming a sacrificial stud at a bottom portion of the first via opening; forming a power rail via at a top portion of the first via opening directly above the sacrificial stud; removing the sacrificial stud from a backside of the substrate to create a second via opening exposing the power rail via; replacing a portion of a semiconductor layer surrounding the second via opening with an isolation spacer; and filling the second via opening with a conductive material, thereby forming a backside via that is conductively connected to the power rail via. By replacing the portion of the semiconductor layer with an isolation spacer, embodiments of present invention reduce the risk of shorting the subsequently formed backside via to source/drain regions of the first and the second transistor via the semiconductor layer.

In one embodiment, the portion of the semiconductor layer surrounding the second via opening is vertically between a shallow trench isolation (STI) layer and a backside capping layer.

In another embodiment, replacing the portion of the semiconductor layer surrounding the second via opening includes selectively removing the portion of the semiconductor layer relative to the STI layer and the backside capping layer to create indents; filling the indents and the second via opening with a dielectric material; and re-creating the second via opening in a directional etch process that exposes a bottom surface of the power rail via and leaves portions of the dielectric material in the indents forming the isolation spacer.

In yet another embodiment, creating the first via opening includes selectively removing a section of a trench insulator between the first and the second transistor to create an opening; and extending the opening vertically into the STI layer, the semiconductor layer, and an etch-stop layer below the first and the second transistor, thereby creating the first via opening.

According one embodiment, the method further includes selectively removing the etch-stop layer, from the backside of the substrate, to expose the semiconductor layer and the sacrificial stud; depositing the backside capping layer on top of the semiconductor layer and the sacrificial stud; and applying a chemical-mechanical-polishing (CMP) process to planarize a bottom surface of the backside capping layer and expose a bottom surface of the sacrificial stud.

Embodiments of present invention provide a semiconductor structure. The semiconductor structure includes a first and a second transistor; a power rail via between the first and the second transistor; and a backside via below the power rail via, a middle portion of the backside via being surrounded by an isolation spacer.

In one embodiment, the isolation spacer is vertically between a shallow trench isolation (STI) layer and a backside capping layer, the STI layer surrounding a top portion of the backside via and a lower portion of the power rail via and the backside capping layer surrounding a bottom portion of the backside via.

In another embodiment, the isolation spacer is surrounded by a semiconductor layer.

In yet another embodiment, sidewalls of the backside via are substantially aligned with sidewalls of the power rail via.

In a further embodiment, a source/drain region of the first transistor is conductively connected to the power rail via through a source/drain contact.

In yet a further embodiment, a bottom surface of the backside via is conductively connected to a metal line of a backside metal level.

### BRIEF DESCRIPTION OF THE DRAWINGS

The present invention will be understood and appreciated more fully from the following detailed description of embodiments of present invention, taken in conjunction with accompanying drawings of which:

FIGS. 1A, 1B, and 1C to FIGS. 15A, 15B, and 15C are demonstrative illustrations of cross-sectional views of a semiconductor structure at various steps of manufacturing thereof according to embodiments of present invention; and

FIG. 16 is a demonstrative illustration of a flow-chart of a method of manufacturing a semiconductor structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

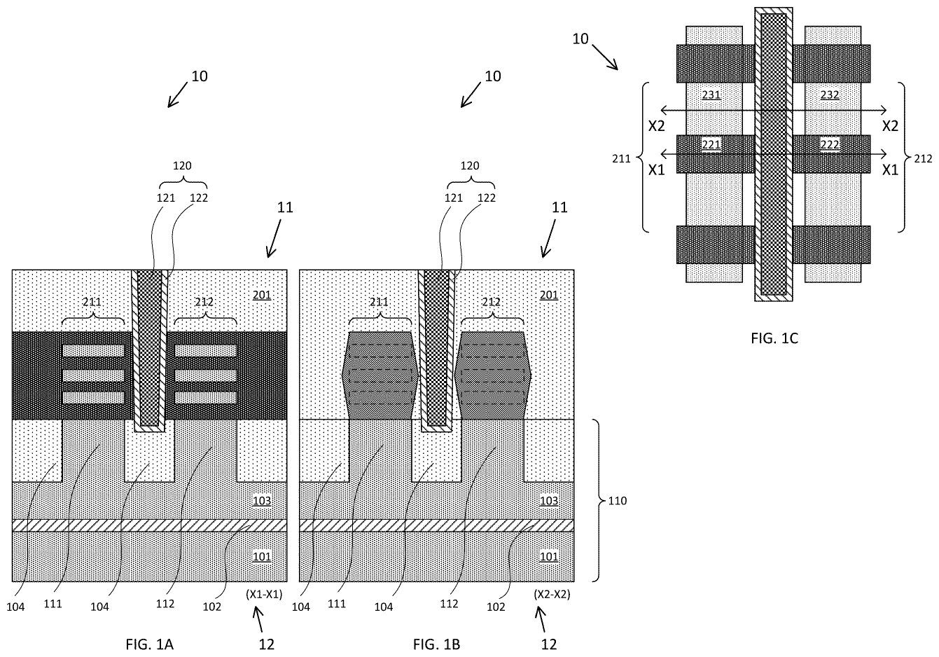

FIGS. 1A, 1B, and 1C are demonstrative illustrations of different cross-sectional views and a simplified top view of a semiconductor structure at a step of manufacturing thereof according to embodiments of present invention. As a non-limiting example, the semiconductor structure is illustrated to include, for example, a first and a second transistor such as a first and a second nanosheet transistor and embodiments of present invention provide forming a backside via that contacts or connects to a power rail via where the power rail via is formed, for example, in a cell boundary area between the first and the second nanosheet transistor.

More specifically, FIG. 1A illustrates a cross-sectional view of a semiconductor structure, where the cross-section is made along a line X1-X1, as illustrated in FIG. 1C, across a first and a second gate of a first and a second nanosheet transistor respectively. In other words, the line X1-X1 is made in a first direction along a width of the first and the second gate. FIG. 1B illustrates a cross-sectional view of the semiconductor structure, where the cross-section is made along a line X2-X2, as is illustrated in FIG. 1C, across a first and a second source/drain region of the first and the second nanosheet transistor respectively. In other words, the line X2-X2 is made in a second direction along a width of the first and the second source/drain region, and thus parallel to the first direction. FIG. 1C is a simplified top view of the semiconductor structure. Because the main purpose of FIG. 1C is to illustrate where the cross-sections illustrated in FIG. 1A and FIG. 1B are, FIG. 1C may illustrate only key elements of the semiconductor structure such as channels, gate, and source/drain regions. Other elements such as spacers, dielectric caps etc. may not necessarily be illustrated in order not to overcrowd the drawing.

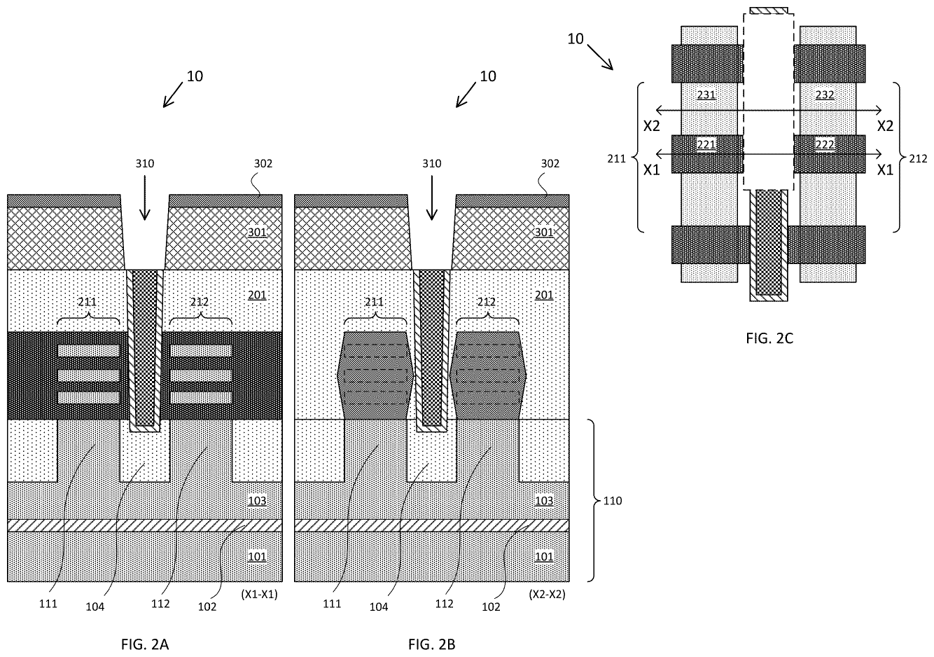

Likewise, FIGS. 2A, 2B, and 2C to FIGS. 15A, 15B, and 15C are demonstrative cross-sectional views and simplified top views of the semiconductor structure, at different manufacturing steps, and are illustrated in manners similar to FIGS. 1A, 1B, and 1C respectively.

Reference is made back to FIGS. 1A, 1B, and 1C, embodiments of present invention provide forming a semiconductor structure 10 that is demonstratively illustrated to include, for example, a first transistor such as a first nanosheet transistor 211 and a second transistor such as a second nanosheet transistor 212. However, embodiments of present invention are not limited in this aspect and may be applied to other types of transistors and/or active devices. The first and the second nanosheet (NS) transistor 211 and 212 may be formed on top of, such as on a frontside 11 of, a semiconductor substrate 110 and embedded in or surrounded by a dielectric layer 201. The semiconductor substrate 110 may include, from a backside 12 thereof, a bulk substrate 101, an etch-stop-layer (ESL) 102 on top of the bulk substrate 101, and a semiconductor layer 103 such as a silicon (Si) layer on top of the ESL 102. In one embodiment, the semiconductor substrate 110 may be a silicon-on-insulator (SOI) substrate. In another embodiment, the semiconductor substrate 110 may be a silicon-germanium-on-insulator (SiGeOI) layer with the semiconductor layer 103 being a layer of silicon-germanium (SiGe) or other semiconductor materials.

In one embodiment, the first NS transistor 211 may be formed on top of a first portion 111 of the substrate 110 and the second NS transistor 212 may be formed on top of a second portion 112 of the substrate 110. A shallow-trench-isolation (STI) layer 104 may be formed on top of the substrate 110 that surrounds the first and the second portion 111 and 112 of the substrate 110. In one embodiment, the STI layer 104 may be a dielectric layer embedded in the substrate 110 and more particularly embedded in the semiconductor layer 103.

According to one embodiment of present invention, a trench insulator 120 may be formed in regions, as is illustrated FIG. 1C, between a first and a second gate 221 and 222 of the first and the second NS transistor 211 and 212, and between a first and a second source/drain (S/D) region 231 and 232 of the first and the second NS transistor 211 and 212. The trench insulator 120, which may be referred to as a CT cut as well, may include a dielectric fill 121 surrounded by a liner 122 at sidewalls and a bottom thereof. In one embodiment, a lower portion of the trench insulator 120 may be embedded in the STI layer 104 between the first and the second NS transistor 211 and 212.

FIGS. 2A, 2B, and 2C are demonstrative illustrations of different cross-sectional views and a simplified top view of a semiconductor structure at a step of manufacturing thereof according to embodiments of present invention. More particularly, following the step illustrated in FIGS. 1A, 1B, and 1C, embodiments of present invention provide forming a mask on top of the trench insulator 120 to expose only a portion of the trench insulator 120. In doing so, embodiments of present invention provide forming or depositing an organic planarization (OPL) layer 301 on top of the dielectric layer 201, covering the trench insulator 120, and a silicon-containing arti-reflective-coating (SiARC) layer 302 on top of the OPL layer 301. A lithographic patterning and etching process may subsequently be applied to pattern the OPL layer 301 thereby forming the OPL layer 301 into a hard mask. The hard mask may include an opening 310 that exposes a portion of the trench insulator 120, particularly the portion between the first and the second gate 221 and 222 and between the first and the second S/D region 231 and 232 of the first and the second NS transistor 211 and 212.

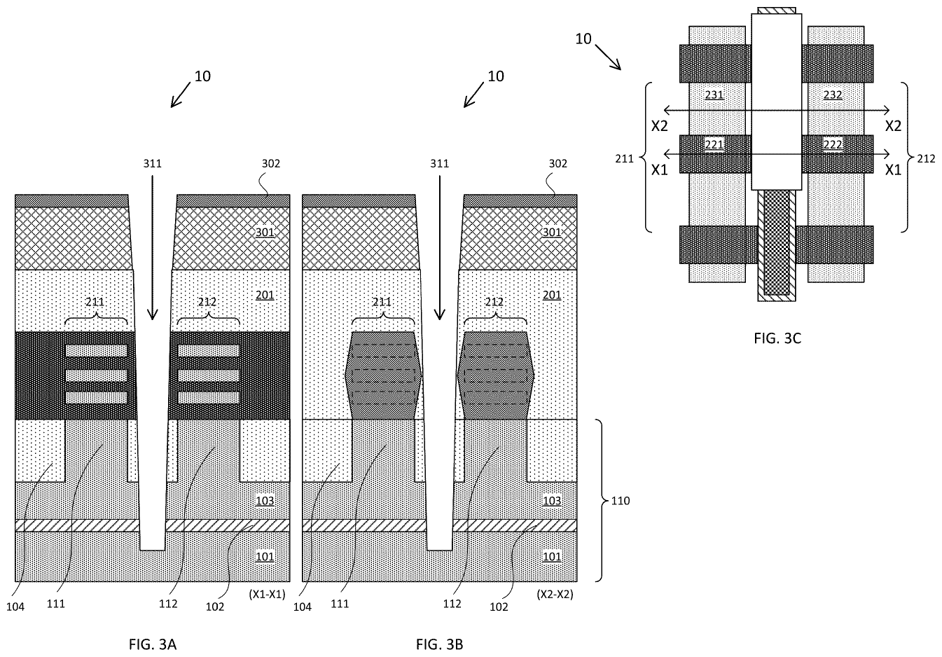

FIGS. 3A, 3B, and 3C are demonstrative illustrations of different cross-sectional views and a simplified top view of a semiconductor structure at a step of manufacturing thereof according to embodiments of present invention. More particularly, following the step illustrated in FIGS. 2A, 2B, and 2C, embodiments of present invention provide selectively etching the exposed portion of the trench insulator 120 to create an opening between the first and the second NS transistor 211 and 212, more particularly between the first and the second gate 221 and 222 and between the first and the second S/D region 231 and 232. Embodiments of present invention provide further extending the opening, through an anisotropic etch process such as a reactive-ion-etch (RIE) process, into the STI layer 104 underneath the removed portion of the trench insulator 120, the semiconductor layer 103 below the STI layer 104, the ESL 102 below the semiconductor layer 103, and partially into the bulk substrate 101 below the ESL 102. Embodiments of present invention thereby creates a first via opening 311 that extends deeply into the substrate 110, in a cell boundary area between the first and the second NS transistor 211 and 212.

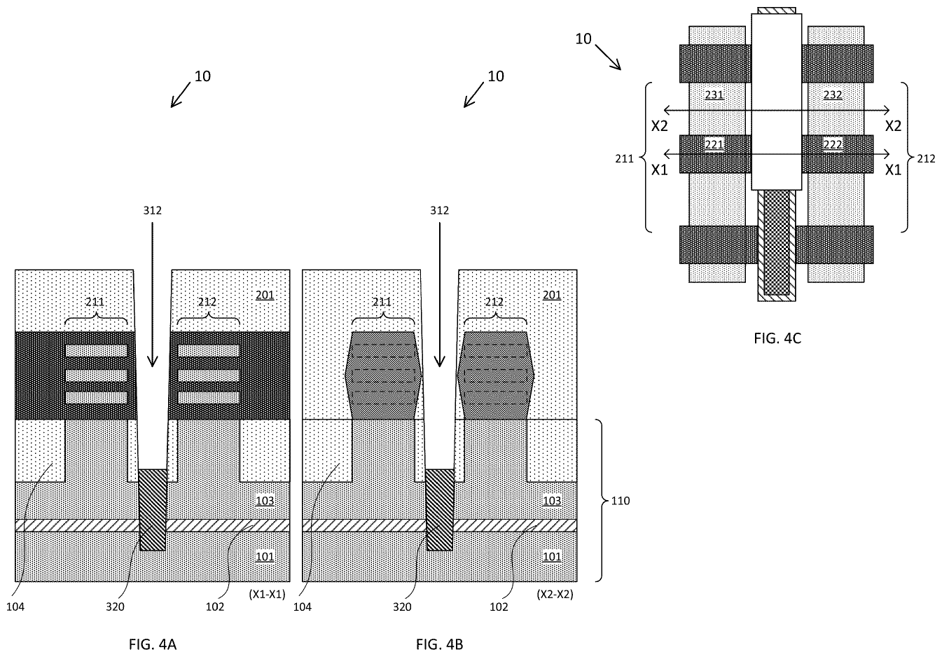

FIGS. 4A, 4B, and 4C are demonstrative illustrations of different cross-sectional views and a simplified top view of a semiconductor structure at a step of manufacturing thereof according to embodiments of present invention. More particularly, following the step illustrated in FIGS. 3A, 3B, and 3C, embodiments of present invention provide partially filling the first via opening 311, such as at a bottom portion thereof, with a sacrificial material to form a sacrificial stud 320. The sacrificial material may include, for example, titanium-oxide (TiOx), silicon-carbide (SiC), or other suitable materials. In one embodiment, the sacrificial material may initially be deposited into the first via opening 311 to completely fill the first via opening 311. A chemical-mechanical-polishing (CMP) process may then be applied to planarize a top surface of the deposited sacrificial material layer. Next, the sacrificial material layer may be recessed in the first via opening 311 down to a level that is, for example, below the first and the second gate 221 and 222 and below the first and the second S/D region 231 and 232, thereby forming a sacrificial stud 320. For example, in one embodiment the sacrificial stud 320 may be formed to have a top surface that is below a top surface of the substrate 110 such as below a top surface of the semiconductor layer 103 that is surrounded by the STI layer 104. In another embodiment, the top surface of the sacrificial stud 320 may be above a bottom surface of the STI layer 104 such that a top portion of the sacrificial stud 320 may be surrounded by the STI layer 104. The sacrificial stud 320 may downwardly extrude the ESL 102 to have a bottom portion below the ESL 102. The formation of the sacrificial stud 320 at the bottom portion of the first via opening 311 results in a via opening 312 above the sacrificial stud 320.

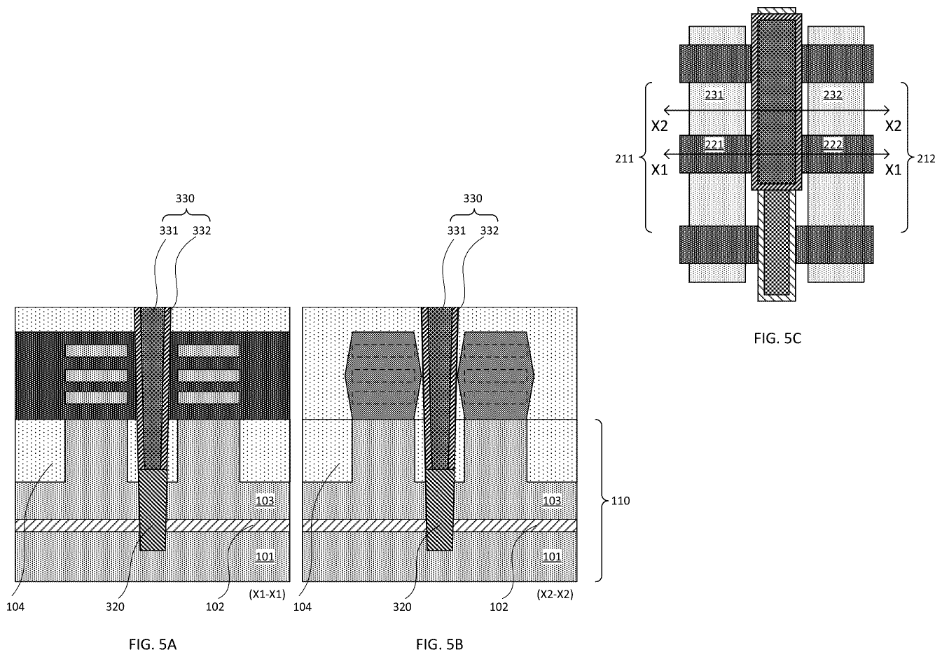

FIGS. 5A, 5B, and 5C are demonstrative illustrations of different cross-sectional views and a simplified top view of a semiconductor structure at a step of manufacturing thereof according to embodiments of present invention. More particularly, following the step illustrated in FIGS. 4A, 4B, and 4C, embodiments of present invention provide forming a power rail via 330 in the via opening 312 about the sacrificial stud 320. In forming the power rail via 330, embodiments of present invention provide first forming a conformal dielectric layer lining the via opening 312 and subsequently applying a directional and/or anisotropic etch process to remove horizontal portion of the conformal dielectric layer thereby forming a core liner 332 of the power rail via 330. The core liner 332 covers sidewalls of the via opening 312 and leaves the sacrificial stud 320 being exposed at the bottom of the via opening 312. Next, conductive material such as copper (Cu), aluminum (Al), tungsten (W) may be deposited in the remaining opening of the via opening 312 surrounded by the core liner 332, in a metallization process, to form a conductive core 331 of the power rail via 330. The conductive core 331 is in direct contact with the sacrificial stud 320 and the core liner 332 lines or covers the conductive core 331 at sidewalls of the power rail via 330.

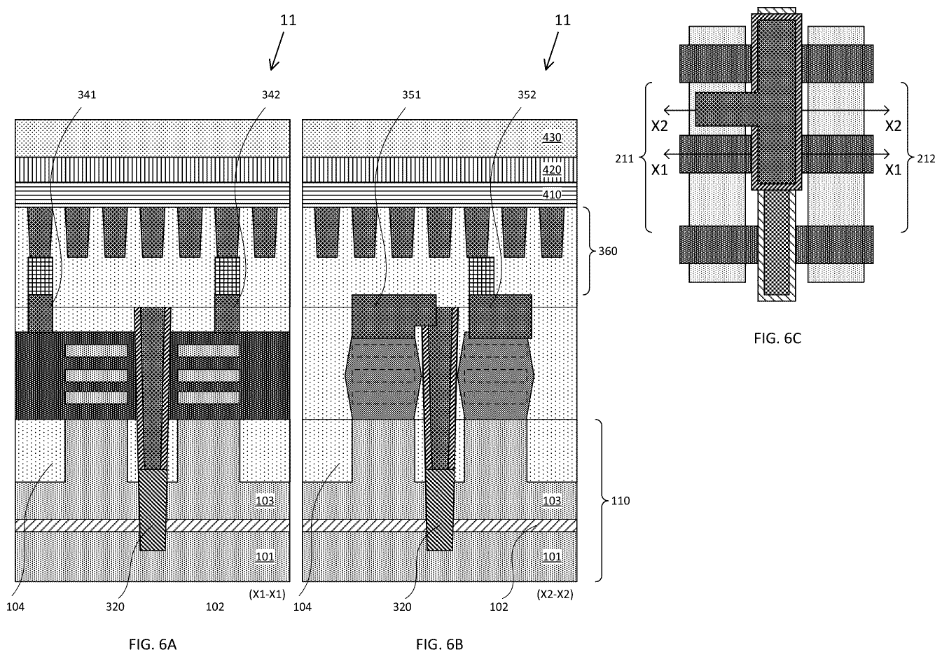

FIGS. 6A, 6B, and 6C are demonstrative illustrations of different cross-sectional views and a simplified top view of a semiconductor structure at a step of manufacturing thereof according to embodiments of present invention. More particularly, following the step illustrated in FIGS. 5A, 5B, and 5C, embodiments of present invention provide forming S/D contacts and/or gate contacts to the first and the second NS transistor 211 and 212. For example, a first gate contact 341 and a second gate contact 342 may be formed to contact the gates 221 and 222 of the first NS transistor 211 and the second NS transistor 212 and a first S/D contact 351 and a second S/D contact 352 may be formed to contact the S/D regions 231 and 232 of the first NS transistor 211 and the second NS transistor 212. More specifically, for example, the first S/D contact 351 may be formed such that it contacts the power rail via 330 as well, across the core liner 332 to be in contact with or connected to the conductive core 331 of the power rail via 330. By connecting the first S/D contact 351 with the power rail via 330, as being described below in more details, power supply and/or signal routing function may be provided to the S/D region 231 of the first NS transistor 211 through the power rail via 330, from a backside power distribution network (BSPDN).

After forming the S/D contacts and/or gate contacts, embodiments of present invention provide forming a first metal level (M1) including a plurality of metal lines in a dielectric layer 360 on top of the S/D contacts 351 and 352 and/or gate contacts 341 and 342. One or more of the plurality of metal lines may be formed to be in contact with the S/D contacts 351 and 352 and/or gate contacts 341 and 342 through one or more conductive vias (V0). Next, additional metal levels and other interconnect structures, such as a back-end-of-line (BEOL) structure 410, may be formed on top of the dielectric layer 360. The BEOL structure 410 provides power supply and/or signal routing functions to the first and the second NS transistor 211 and 212 from the frontside 11 of the semiconductor structure 10.

Next, a carrier wafer 430 may be bonded onto the semiconductor structure 10 through a bonding agent 420 such as a layer of bonding oxide. With the carrier wafer 430 being attached thereto, the semiconductor structure 10 may be flipped upside-down for further processing from the backside 12 of the semiconductor structure 10. However, for the ease of understanding and avoidance of confusion, subsequent drawings will continue to be made or illustrated in an upside-up fashion and the structural description will be made in accordance with that orientation of illustration.

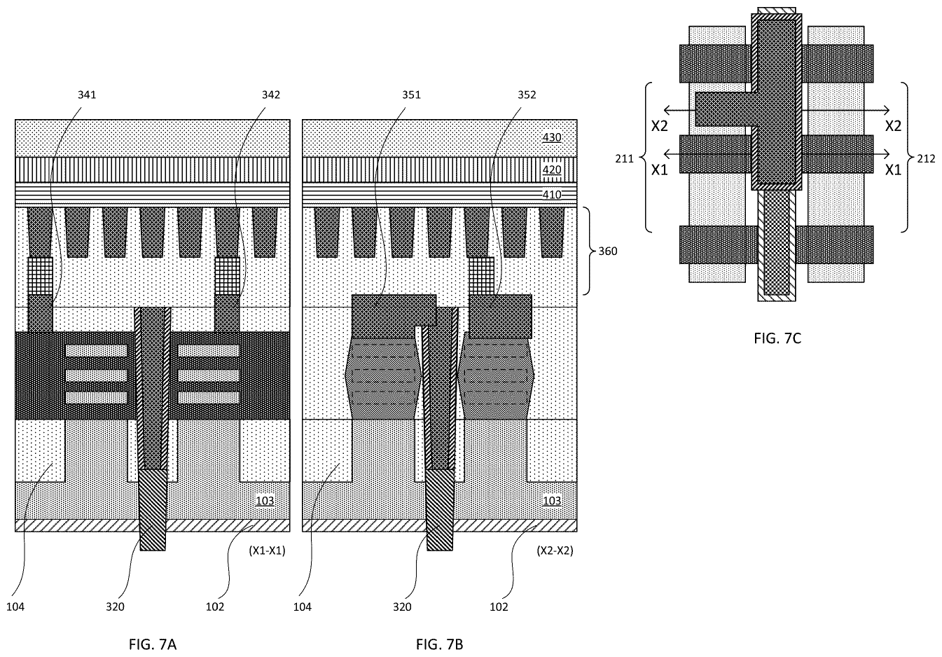

FIGS. 7A, 7B, and 7C are demonstrative illustrations of different cross-sectional views and a simplified top view of a semiconductor structure at a step of manufacturing thereof according to embodiments of present invention. More particularly, following the step illustrated in FIGS. 6A, 6B, and 6C, embodiments of present invention provide removing the bulk substrate 101 of the semiconductor substrate 110. The removal process may be a selective etch process, such as a wet etch process, and selective to both the ESL 102 and the sacrificial stud 320. As being described above, the sacrificial stud 320 downwardly extrudes the ESL 102 and therefore, after the removal of the bulk substrate 101, may be partially exposed.

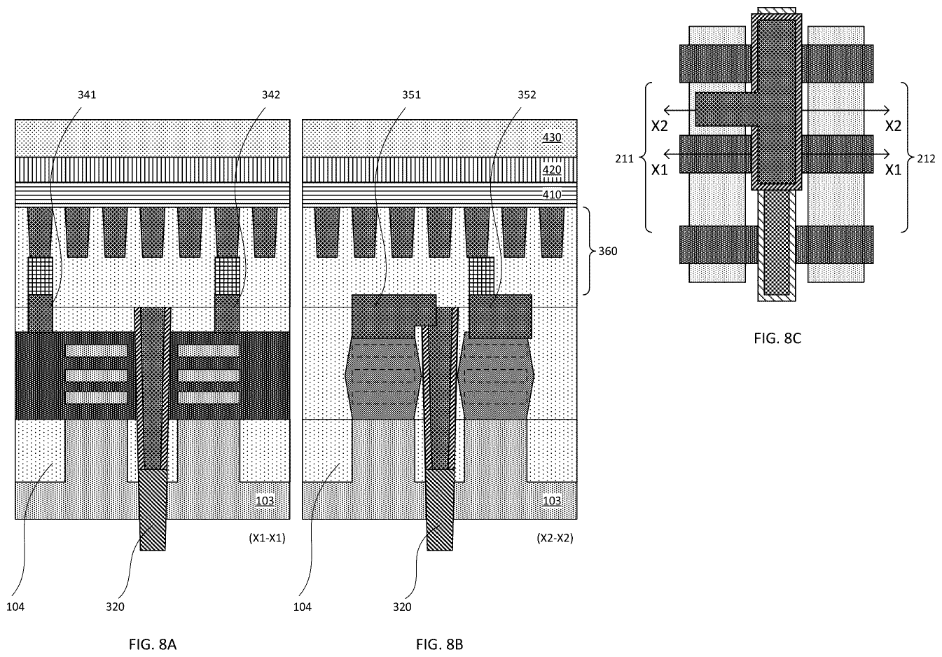

FIGS. 8A, 8B, and 8C are demonstrative illustrations of different cross-sectional views and a simplified top view of a semiconductor structure at a step of manufacturing thereof according to embodiments of present invention. More particularly, following the step illustrated in FIGS. 7A, 7B, and 7C, embodiments of present invention provide continuing to remove the ESL 102 in an etch process that is selective to the sacrificial stud 320. For example, the ESL 102 may be made of SiOx or SiN material and the sacrificial stud 320 may be made of TiOx or SiC material. The material of SiOx or SiN may be selectively removed or etched away without substantially removing the material of TiOx or SiC that forms the sacrificial stud 320. The removal of the ESL 102 exposes the semiconductor layer 103 that surrounds a portion of the sacrificial stud 320.

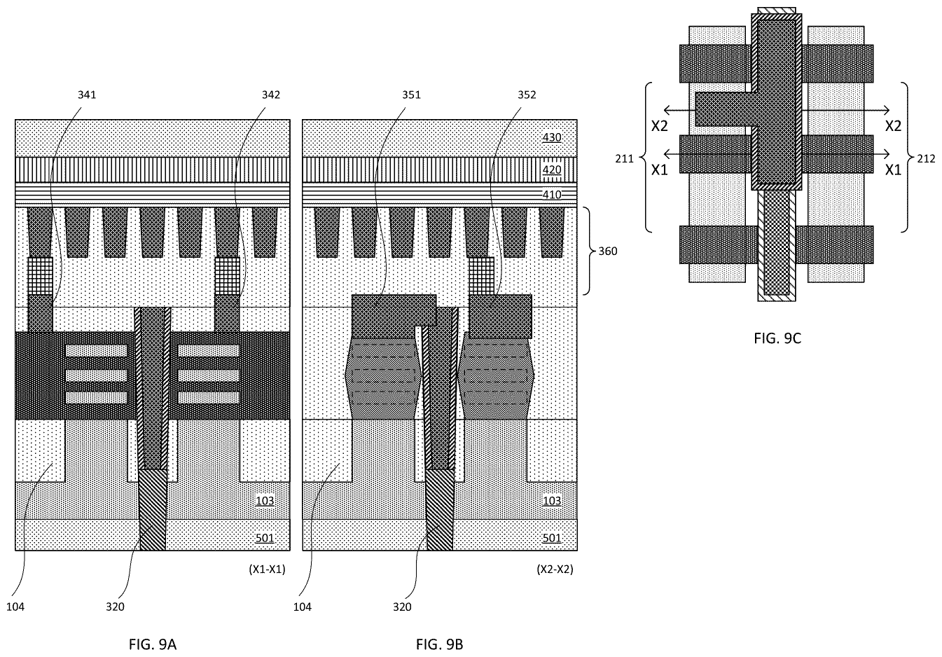

FIGS. 9A, 9B, and 9C are demonstrative illustrations of different cross-sectional views and a simplified top view of a semiconductor structure at a step of manufacturing thereof according to embodiments of present invention. More particularly, following the step illustrated in FIGS. 8A, 8B, and 8C, embodiments of present invention provide forming, such as through a deposition process, a backside capping layer 501 covering the exposed sacrificial stud 320 and at the bottom surface of the semiconductor layer 103. The deposition of the backside capping layer 501 may be followed by a chemical-mechanical-polishing (CMP) process to planarize a bottom surface of the backside capping layer 501 such that the sacrificial stud 320 may become coplanar with the bottom surface of the backside capping layer 501 and be exposed. The backside capping layer 501 may be a layer of SiOx, SiN, or other suitable materials.

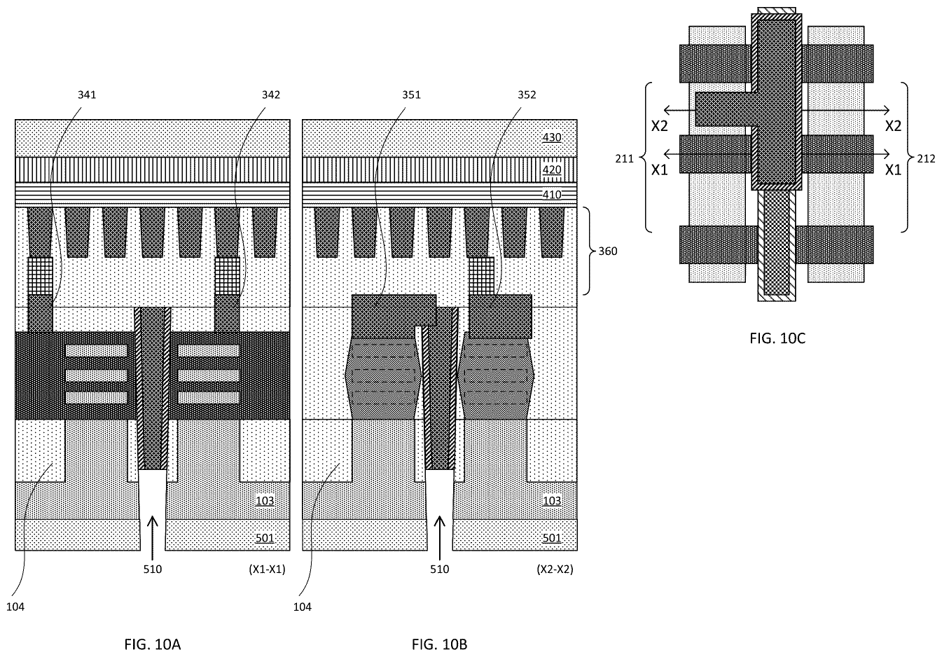

FIGS. 10A, 10B, and 10C are demonstrative illustrations of different cross-sectional views and a simplified top view of a semiconductor structure at a step of manufacturing thereof according to embodiments of present invention. More particularly, following the step illustrated in FIGS. 9A, 9B, and 9C, embodiments of present invention provide selectively removing the sacrificial stud 320 to expose a bottom surface of the power rail via 330 such as to expose a bottom surface of the conductive core 331 of the power rail via 330. The selective removal of the sacrificial stud 320 may create a second via opening 510. The second via opening 510 may extend through the backside capping layer 501, the semiconductor layer 103, and the STI layer 104 that partially surrounds the power rail via 330.

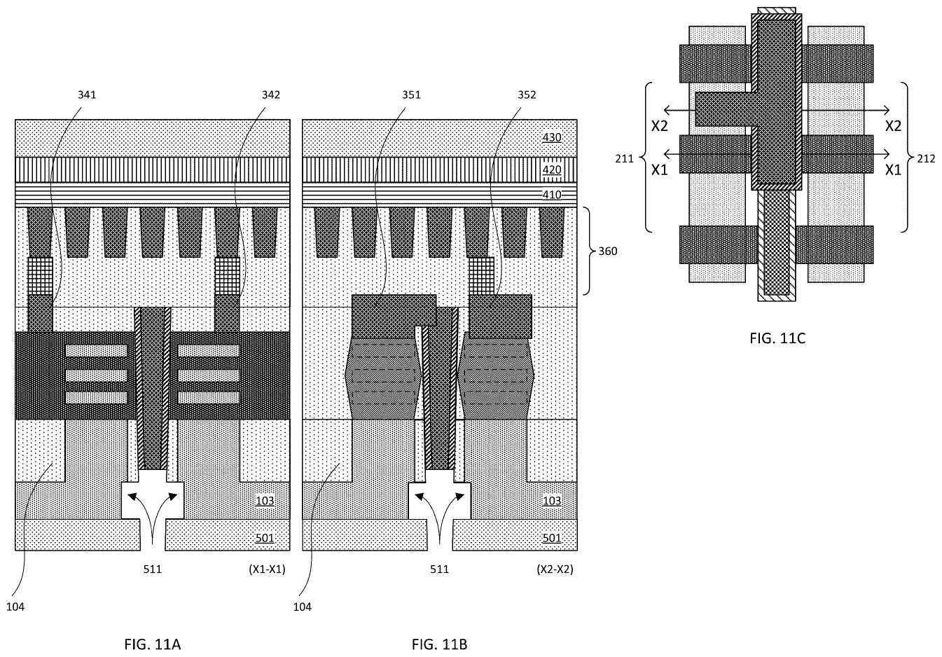

FIGS. 11A, 11B, and 11C are demonstrative illustrations of different cross-sectional views and a simplified top view of a semiconductor structure at a step of manufacturing thereof according to embodiments of present invention. More particularly, following the step illustrated in FIGS. 10A, 10B, and 10C, embodiments of present invention provide replacing a portion of the semiconductor layer 103 that surrounds the second via opening 510 with isolation spacers. For example, embodiments of present invention provide performing indentation in the semiconductor layer 103 exposed at sidewalls of the second via opening 510. For example, a selective etch process may be applied to etch a portion of the semiconductor layer 103 that is vertically between the STI layer 104 and the backside capping layer 501. In other words, with the semiconductor layer 103 being for example silicon and both the STI layer 104 and the backside capping layer 501 being for example dielectric material, the selective etch process may etch the semiconductor layer 103 relative to the STI layer 104 and the backside capping layer 501. As a result, the selective etch process may leave the STI layer 104 and the backside capping layer 501, above and below the semiconductor layer 103, substantially unetched or unaffected. The selective etch process extends a middle section of the second via opening 510 horizontally to create indents 511.

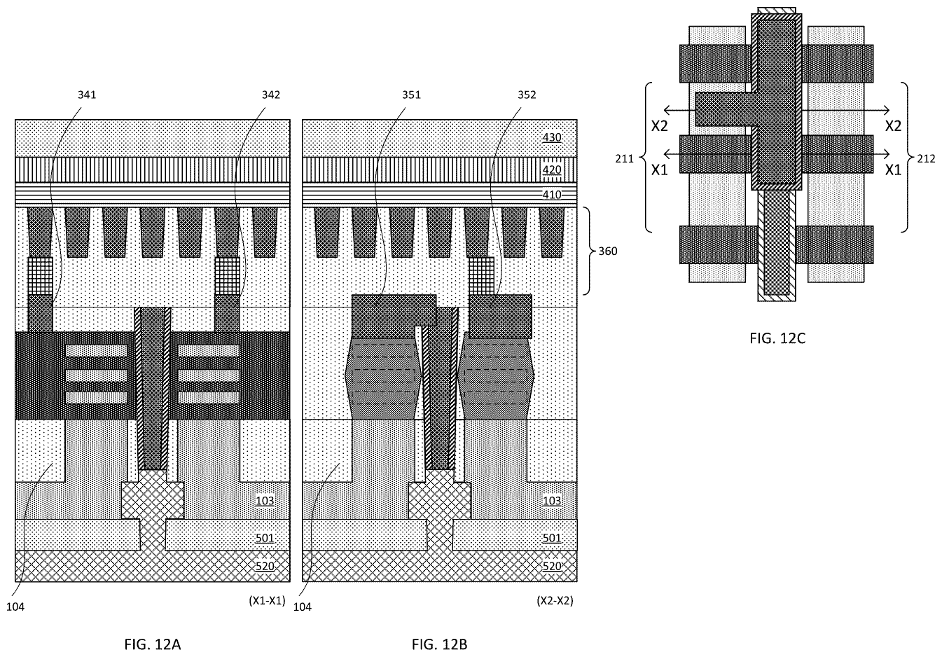

FIGS. 12A, 12B, and 12C are demonstrative illustrations of different cross-sectional views and a simplified top view of a semiconductor structure at a step of manufacturing thereof according to embodiments of present invention. More particularly, following the step illustrated in FIGS. 11A, 11B, and 11C, embodiments of present invention provide forming an isolation spacer in the indents 511. In doing so, embodiments of present invention provide, from the backside 12 of the semiconductor structure 10, filling the second via opening 510 and the indents 511 with a dielectric material. The dielectric material may be, for example, flowable oxide, flowable silicon-oxy-carbide (SiOC), or other suitable dielectric materials. The dielectric material may fill the indents 511, the second via opening 510, and cover the backside capping layer 501 to form a dielectric layer 520.

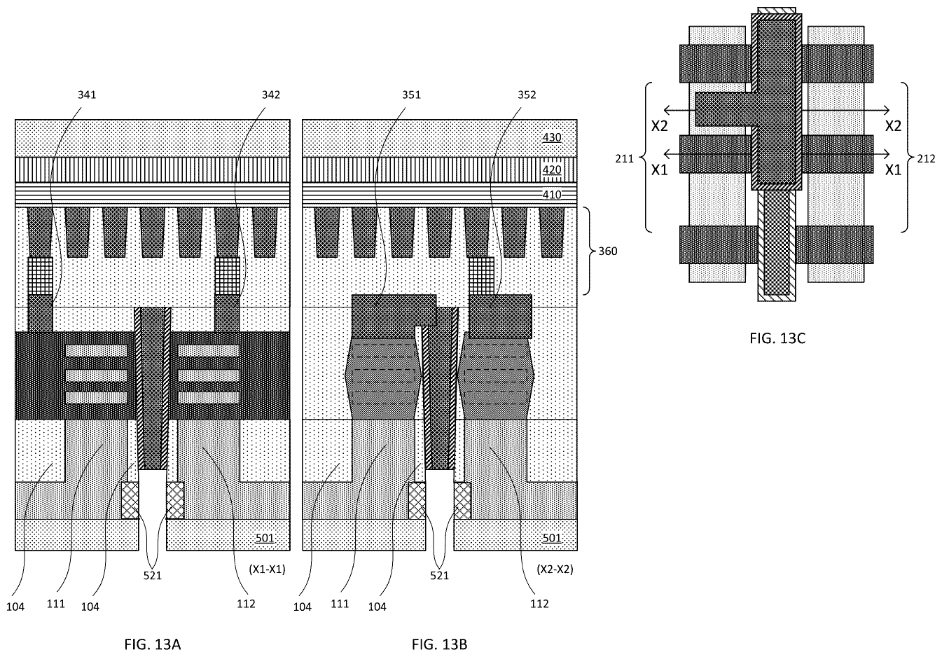

FIGS. 13A, 13B, and 13C are demonstrative illustrations of different cross-sectional views and a simplified top view of a semiconductor structure at a step of manufacturing thereof according to embodiments of present invention. More particularly, following the step illustrated in FIGS. 12A, 12B, and 12C, embodiments of present invention provide applying a CMP process to remove the excessive portion of the dielectric layer 520 at the top of the backside capping layer 501. Next, a selective anisotropic etch process, such as a RIE process, may be applied to re-create the second via opening 510 by selectively etching thereby removing the dielectric layer 520 directly underneath the power rail via 330, thereby leaving portions of the dielectric layer 520 in the indents 511 to form an isolation spacer 521. By the nature of the selective etching of the semiconductor layer 103 in forming the indents 511, a bottom surface of the isolation spacer 521 formed in the indents 511 may be coplanar with a top surface of the backside capping layer 501. In one embodiment, sidewalls of the isolation spacer 521, the backside capping layer 501, and the STI layer 104 in the second via opening 510 may be substantially aligned with each other and aligned with sidewalls of the power rail via 330.

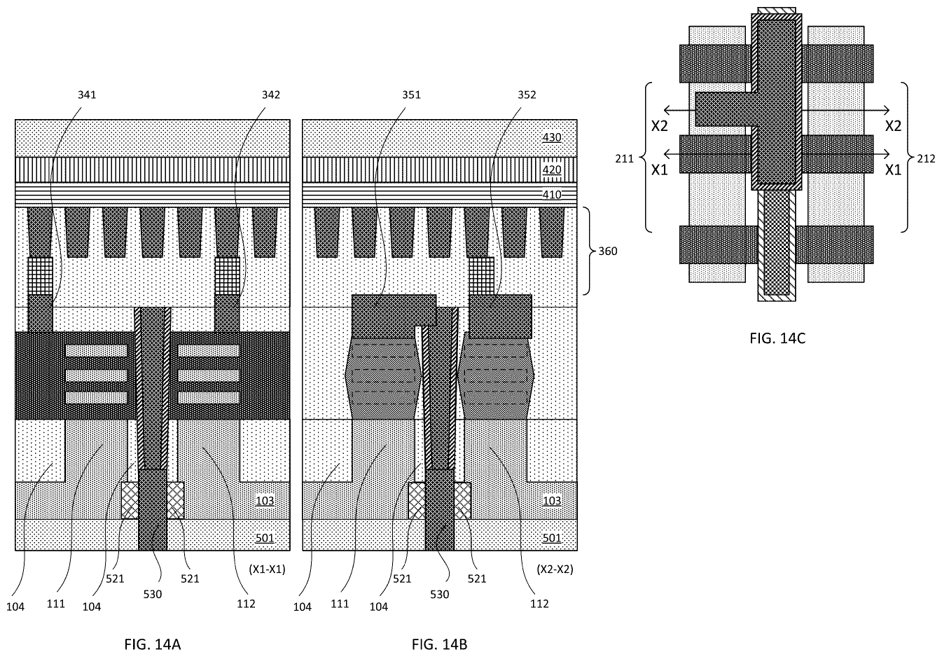

FIGS. 14A, 14B, and 14C are demonstrative illustrations of different cross-sectional views and a simplified top view of a semiconductor structure at a step of manufacturing thereof according to embodiments of present invention. More particularly, following the step illustrated in FIGS. 13A, 13B, and 13C, embodiments of present invention provide filling the second via opening 510 with a conductive material such as, for example, W or Cu to form a backside via 530. Because the second via opening 510 is surrounded by dielectric materials of the STI layer 104, the isolation spacer 521, and the backside capping layer 501, the backside via 530 may be formed without the need to form a liner first. In other words, the backside via 530 may be formed to be linerless. After filling the second via opening 510 with the conductive material, a CMP process may be applied to planarize a bottom surface of the formed backside via 530 to be coplanar with a bottom surface of the backside capping layer 501.

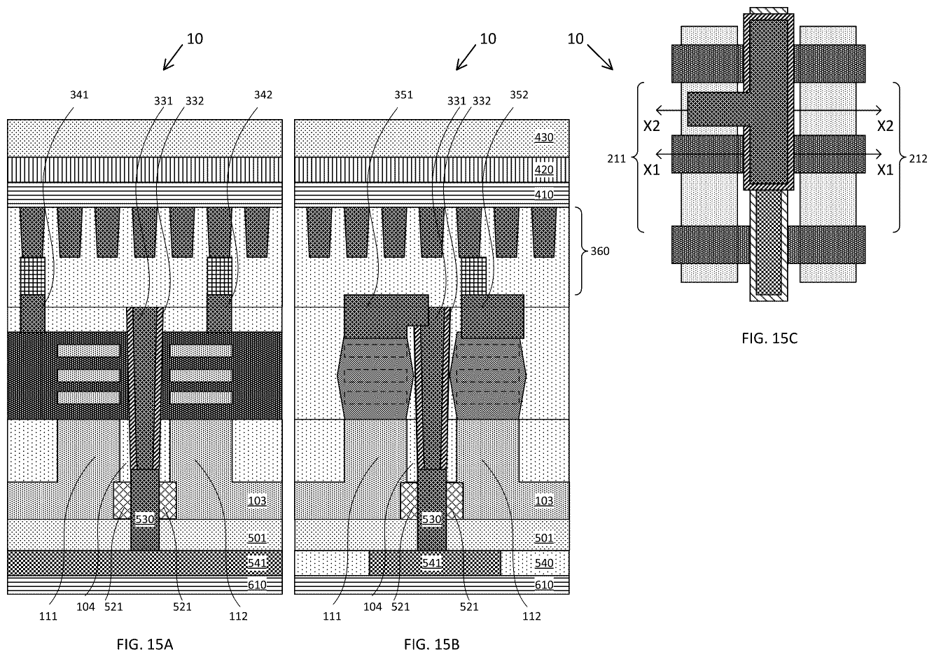

FIGS. 15A, 15B, and 15C are demonstrative illustrations of different cross-sectional views and a simplified top view of a semiconductor structure at a step of manufacturing thereof according to embodiments of present invention. More particularly, following the step illustrated in FIGS. 14A, 14B, and 14C, embodiments of present invention provide forming a backside metal level such as a backside metal 1 (BM1) with one or more metal lines such as a backside metal line 541 in a backside dielectric layer 540. The backside metal line 541 may be formed to be directly connected to or in contact with the backside via 530. The backside via 530 in-turn is in contact with the power rail via 330. Because the S/D contact 351 of the first NS transistor 211 is formed in contact with the power rail via 330, the first NS transistor 211 may be powered through the backside metal line 541.

Additional backside metal lines and/or interconnect structures, such as a backside BEOL structure 610, may be formed directly underneath the dielectric layer 540 and the backside metal line 541.

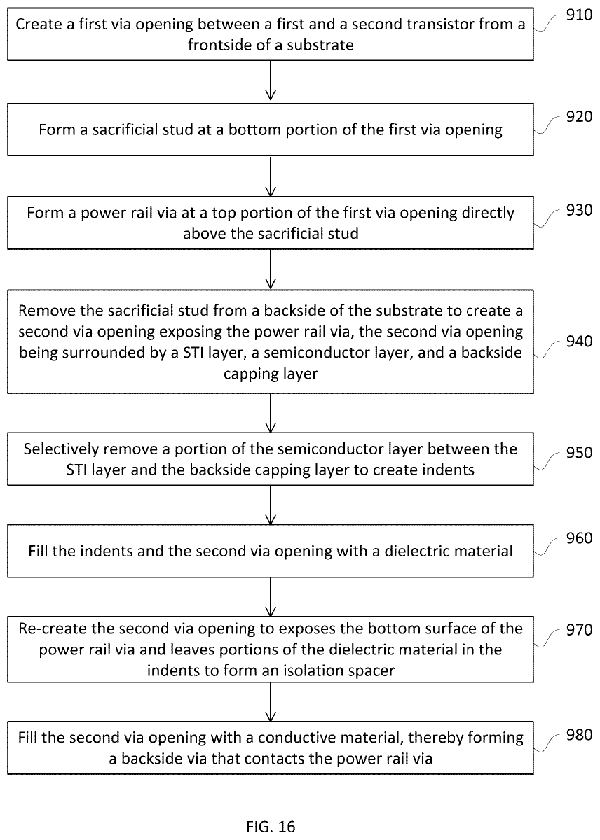

FIG. 16 is a demonstrative illustration of a flow-chart of a method of manufacturing a semiconductor structure according to embodiments of present invention. The method includes (910) creating a first via opening between a first and a second transistor from a frontside of a substrate; (920) forming a sacrificial stud at a bottom portion of the first via opening; (930) forming a power rail via at a top portion of the first via opening directly above the sacrificial stud; (940) removing the sacrificial stud from a backside of the substrate to create a second via opening exposing the power rail via, the second via opening being surrounded by a STI layer, a semiconductor layer, and a backside capping layer; (950) selectively remove a portion of the semiconductor layer between the STI layer and the backside capping layer to create indents; (960) filling the indents and the second via opening with a dielectric material; (970) re-creating the second via opening to exposes the bottom surface of the power rail via and leaves portions of the dielectric material in the indents to form an isolation spacer; and (980) filling the second via opening with a conductive material, thereby forming a backside via that contacts the power rail via.

Various examples may possibly be described by one or more of the following features in the following numbered clauses:
Clause 1: A semiconductor structure comprising a first and a second transistor; a power rail via between the first and the second transistor; a backside via below the power rail via, the backside via having a first portion directly contacting the power rail via and a second portion underneath the first portion; and an isolation spacer surrounding the second portion of the backside via.
Clause 2: The semiconductor structure of clause 1, further comprising a shallow trench isolation (STI) layer, the STI layer surrounding the first portion of the backside via.
Clause 3: The semiconductor structure of clause 2, wherein the STI layer surrounds a lower portion of the power rail via and is directly on top of the isolation spacer.
Clause 4: The semiconductor structure of clause 1, further comprising a backside capping layer, wherein the backside via has a third portion underneath the second portion and the backside capping layer surrounds the third portion of the backside via.
Clause 5: The semiconductor structure of clause 4, wherein sidewalls of the first portion, the second portion, and the third portion of the backside via are vertically aligned with one another and substantially vertically aligned with sidewalls of the power rail via.
Clause 6: The semiconductor structure of clause 5, wherein a top surface of the backside capping layer is coplanar with a bottom surface of the isolation spacer.
Clause 7: The semiconductor structure of clause 1, wherein the power rail via comprises a conductive core and a core liner and the core liner covers the conductive core at sidewalls of the power rail via.
Clause 8: The semiconductor structure of clause 7, wherein the power rail via is insulated from source/drain regions of the first and the second transistor by the core liner.
Clause 9: The semiconductor structure of clause 7, wherein the conductive core of the power rail via is in direct contact with the backside via and a width of the conductive core at a bottom thereof is less than a width of the backside via.
Clause 10: A method of forming a semiconductor structure comprising creating a first via opening between a first and a second transistor from a frontside of a substrate; forming a sacrificial stud at a bottom portion of the first via opening; forming a power rail via at a top portion of the first via opening directly above the sacrificial stud; removing the sacrificial stud from a backside of the substrate to create a second via opening exposing the power rail via; replacing a portion of a semiconductor layer surrounding the second via opening with an isolation spacer; and filling the second via opening with a conductive material, thereby forming a backside via that is conductively connected to the power rail via.
Clause 11: The method of clause 10, wherein the portion of the semiconductor layer surrounding the second via opening is vertically between a shallow trench isolation (STI) layer and a backside capping layer.
Clause 12: The method of clause 11, wherein replacing the portion of the semiconductor layer surrounding the second via opening comprises selectively removing the portion of the semiconductor layer relative to the STI layer and the backside capping layer to create indents; filling the indents and the second via opening with a dielectric material; and re-creating the second via opening in a directional etch process that exposes a bottom surface of the power rail via and leaves portions of the dielectric material in the indents forming the isolation spacer.
Clause 13: The method of clause 11, wherein creating the first via opening comprises selectively removing a section of a trench insulator between the first and the second transistor to create an opening; and extending the opening vertically into the STI layer, the semiconductor layer, and an etch-stop layer below the first and the second transistor, thereby creating the first via opening.
Clause 14: The method of clause 13, further comprising selectively removing the etch-stop layer, from the backside of the substrate, to expose the semiconductor layer and the sacrificial stud; depositing the backside capping layer on top of the semiconductor layer and the sacrificial stud; and applying a chemical-mechanical-polishing (CMP) process to planarize a bottom surface of the backside capping layer and expose a bottom surface of the sacrificial stud.
Clause 15: A semiconductor structure comprising a first and a second transistor; a power rail via between the first and the second transistor; and a backside via below the power rail via, a middle portion of the backside via being surrounded by an isolation spacer.
Clause 16: The semiconductor structure of clause 15, wherein the isolation spacer is vertically between a shallow trench isolation (STI) layer and a backside capping layer, the STI layer surrounding a top portion of the backside via and a lower portion of the power rail via and the backside capping layer surrounding a bottom portion of the backside via.
Clause 17: The semiconductor structure of clause 16, wherein the isolation spacer is surrounded by a semiconductor layer.
Clause 18: The semiconductor structure of clause 17, wherein sidewalls of the backside via are substantially aligned with sidewalls of the power rail via.
Clause 19: The semiconductor structure of clause 15, wherein a source/drain region of the first transistor is conductively connected to the power rail via through a source/drain contact.
Clause 20: The semiconductor structure of clause 15, wherein a bottom surface of the backside via is conductively connected to a metal line of a backside metal level.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A semiconductor structure comprising:
a first and a second transistor;
a power rail via between the first and the second transistor;
a backside via below the power rail via, the backside via having a first portion directly contacting the power rail via and a second portion underneath the first portion; and
an isolation spacer surrounding the second portion of the backside via.

2. The semiconductor structure of claim 1, further comprising a shallow trench isolation (STI) layer, the STI layer surrounding the first portion of the backside via.

3. The semiconductor structure of claim 2, wherein the STI layer surrounds a lower portion of the power rail via and is directly on top of the isolation spacer.

4. The semiconductor structure of claim 1, further comprising a backside capping layer, wherein the backside via has a third portion underneath the second portion and the backside capping layer surrounds the third portion of the backside via.

5. The semiconductor structure of claim 4, wherein sidewalls of the first portion, the second portion, and the third portion of the backside via are vertically aligned with one another and substantially vertically aligned with sidewalls of the power rail via.

6. The semiconductor structure of claim 5, wherein a top surface of the backside capping layer is coplanar with a bottom surface of the isolation spacer.

7. The semiconductor structure of claim 1, wherein the power rail via comprises a conductive core and a core liner and the core liner covers the conductive core at sidewalls of the power rail via.

8. The semiconductor structure of claim 7, wherein the power rail via is insulated from source/drain regions of the first and the second transistor by the core liner.

9. The semiconductor structure of claim 7, wherein the conductive core of the power rail via is in direct contact with the backside via and a width of the conductive core at a bottom thereof is less than a width of the backside via.

10. A method of forming a semiconductor structure comprising:
creating a first via opening between a first and a second transistor from a frontside of a substrate;
forming a sacrificial stud at a bottom portion of the first via opening;
forming a power rail via at a top portion of the first via opening directly above the sacrificial stud;
removing the sacrificial stud from a backside of the substrate to create a second via opening exposing the power rail via;
replacing a portion of a semiconductor layer surrounding the second via opening with an isolation spacer; and
filling the second via opening with a conductive material, thereby forming a backside via that is conductively connected to the power rail via.

11. The method of claim 10, wherein the portion of the semiconductor layer surrounding the second via opening is vertically between a shallow trench isolation (STI) layer and a backside capping layer.

12. The method of claim 11, wherein replacing the portion of the semiconductor layer surrounding the second via opening comprises:
selectively removing the portion of the semiconductor layer relative to the STI layer and the backside capping layer to create indents;
filling the indents and the second via opening with a dielectric material; and
re-creating the second via opening in a directional etch process that exposes a bottom surface of the power rail via and leaves portions of the dielectric material in the indents forming the isolation spacer.

13. The method of claim 11, wherein creating the first via opening comprises:
selectively removing a section of a trench insulator between the first and the second transistor to create an opening; and
extending the opening vertically into the STI layer, the semiconductor layer, and an etch-stop layer below the first and the second transistor, thereby creating the first via opening.

14. The method of claim 13, further comprising:
selectively removing the etch-stop layer, from the backside of the substrate, to expose the semiconductor layer and the sacrificial stud;
depositing the backside capping layer on top of the semiconductor layer and the sacrificial stud; and
applying a chemical-mechanical-polishing (CMP) process to planarize a bottom surface of the backside capping layer and expose a bottom surface of the sacrificial stud.

15. A semiconductor structure comprising:
a first and a second transistor;
a power rail via between the first and the second transistor; and
a backside via below the power rail via, a middle portion of the backside via being surrounded by an isolation spacer.

16. The semiconductor structure of claim 15, wherein the isolation spacer is vertically between a shallow trench isolation (STI) layer and a backside capping layer, the STI layer surrounding a top portion of the backside via and a lower portion of the power rail via and the backside capping layer surrounding a bottom portion of the backside via.

17. The semiconductor structure of claim 16, wherein the isolation spacer is surrounded by a semiconductor layer.

18. The semiconductor structure of claim 17, wherein sidewalls of the backside via are substantially aligned with sidewalls of the power rail via.

19. The semiconductor structure of claim 15, wherein a source/drain region of the first transistor is conductively connected to the power rail via through a source/drain contact.

20. The semiconductor structure of claim 15, wherein a bottom surface of the backside via is conductively connected to a metal line of a backside metal level.
